(19) United States
(12) Patent Application Publication
(10) Pub. No.: US 2025/0204291 A1
(43) Pub. Date: Jun. 19, 2025

(54) SEMICONDUCTOR DEVICE AND MANUFACTURING METHOD OF SEMICONDUCTOR DEVICE

(71) Applicant: SK hynix Inc., Icheon (KR)

(72) Inventors: Beom Seok LEE, Icheon-si (KR); Myoungsub KIM, Icheon-si (KR); Won Jun LEE, Icheon-si (KR)

(21) Appl. No.: 18/589,132

(22) Filed: Feb. 27, 2024

(30) Foreign Application Priority Data
Dec. 13, 2023 (KR) 10-2023-0180486

(51) Int. Cl. H10N 70/00; H10B 63/00

(52) U.S. Cl. CPC H10N 70/8845; H10B 63/80; H10N 70/046; H10N 70/063; H10N 70/066; H10N 70/841; H10N 70/882; H10N 70/8833

(57) ABSTRACT

A semiconductor device may include: a first conductive line; a second conductive line intersecting the first conductive line; a first variable resistance pattern located between the first conductive line and the second conductive line and including a first group 16 element at a first concentration; a second variable resistance pattern located between the first variable resistance pattern and the second conductive line and including a second group 16 element at a second concentration higher than the first concentration; and a diffusion barrier pattern located between the first variable resistance pattern and the second variable resistance pattern.

### CROSS-REFERENCE TO RELATED APPLICATION

This application claims priority under 35 U.S.C. § 119 to Korean Patent Application No. 10-2023-0180486 filed on Dec. 13, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first conductive line; a second conductive line intersecting the first conductive line; a first variable resistance pattern located between the first conductive line and the second conductive line and including a first group 16 element at a first concentration; a second variable resistance pattern located between the first variable resistance pattern and the second conductive line and including a second group 16 element at a second concentration higher than the first concentration; and a diffusion barrier pattern located between the first variable resistance pattern and the second variable resistance pattern.

In an embodiment, a semiconductor device may include: a first conductive line; a second conductive line intersecting the first conductive line; and a memory cell connected between the first conductive line and the second conductive line and including variable resistance patterns and diffusion barrier patterns that are alternately stacked, the variable resistance patterns maintaining their phases after a program operation.

In an embodiment, a manufacturing method of a semiconductor device may include: forming a first electrode layer; forming a first variable resistance layer on the first electrode layer, the first variable resistance layer including a first group 16 element at a first concentration; forming a diffusion barrier layer on the first variable resistance layer; forming a second variable resistance layer on the diffusion barrier layer, the second variable resistance layer including a second group 16 element at a second concentration higher than the first concentration; and forming a second electrode layer on the second variable resistance layer.

### BRIEF DESCRIPTION OF THE DRAWINGS

FIGS. 1A, 1B, and 1C are diagrams for describing a semiconductor device in accordance with an embodiment.

FIGS. 2A and 2B are diagrams for describing a semiconductor device in accordance with an embodiment.

FIG. 3 is a diagram for describing a manufacturing method of a semiconductor device in accordance with an embodiment.

FIG. 4 is a diagram for describing a manufacturing method of a semiconductor device in accordance with an embodiment.

FIGS. 5A, 5B, 5C, and 5D are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

According to the present technology, it is possible to provide a semiconductor device having a stable structure and improved reliability.

As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, only C, or both A and B, or both A and C, or both B and C, or all of A and B and C,” and so on. Hereafter, embodiments in accordance with the technical spirit of the present disclosure will be described with reference to the accompanying drawings.

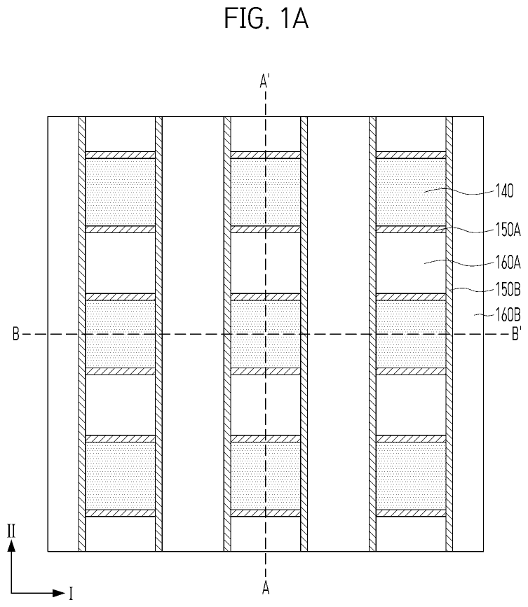

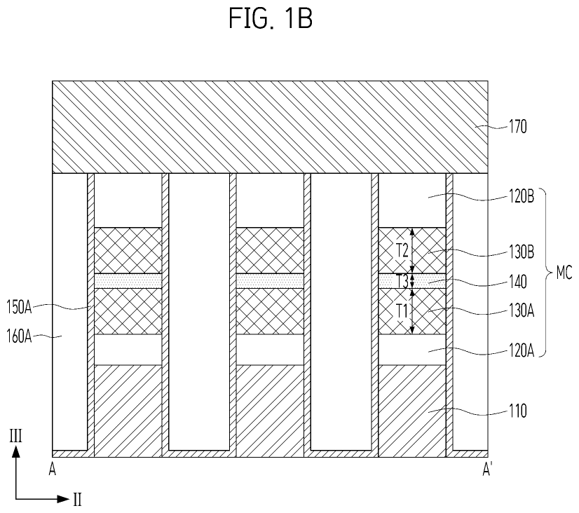

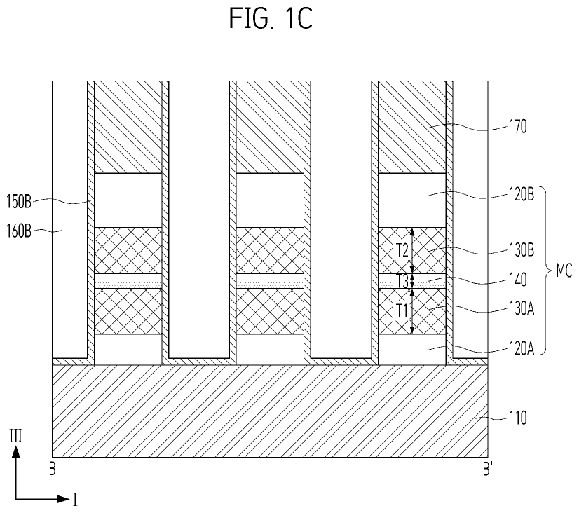

FIGS. 1A to 1C are diagrams for describing a semiconductor device in accordance with an embodiment. FIG. 1A is a plan view, FIG. 1B is a cross-sectional view taken along line A-A′ of FIG. 1A, and FIG. 1C is a cross-sectional view taken along line B-B′ of FIG. 1A.

Referring to FIGS. 1A to 1C, the semiconductor device may include first conductive lines 110, memory cells MC, and second conductive lines 170, or include a combination thereof. The semiconductor device may further include first liner patterns 150A, second liner patterns 150B, first gap-fill patterns 160A, and second gap-fill patterns 160B, or further include a combination thereof.

The first conductive lines 110 may extend in a first direction I. The second conductive lines 170 may intersect the first conductive lines 110, and may be located on the first conductive lines 110. The second conductive lines 170 may extend in a second direction II intersecting the first direction I. As an example, the first conductive lines 110 may be word lines, and the second conductive lines 170 may be bit lines. As another example, the first conductive lines 110 may be bit lines, and the second conductive lines 170 may be word lines.

The memory cells MC may be arranged in the first direction I and the second direction II intersecting the first direction I. The memory cell MC may be located between the first conductive line 110 and the second conductive line 170. The memory cell MC may include at least one of a first variable resistance pattern 130A, a diffusion barrier pattern 140, and a second variable resistance pattern 130B. The memory cell MC may further include at least one of a first electrode pattern 120A and a second electrode pattern 120B.

The first electrode pattern 120A may be a portion of the first conductive line 110 or may be electrically connected to the first conductive line 110. The second electrode pattern 120B may be a portion of the second conductive line 170 or may be electrically connected to the second conductive line 170. The first electrode pattern 120A, or the second electrode pattern 120B, or both may include a conductive material such as polysilicon or metal. For example, the first electrode pattern 120A or the second electrode pattern 120B may include polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), copper (Cu), zinc (Zn), nickel (Ni), cobalt (Co), lead (Pb), platinum (Pt), molybdenum (Mo), ruthenium (Ru), or the like, or include combinations thereof.

The first variable resistance pattern 130A and the second variable resistance pattern 130B may be located between the first conductive line 110 and the second conductive line 170. For example, the first variable resistance pattern 130A may be located between the first conductive line 110 and the second conductive line 170, and the second variable resistance pattern 130B may be located between the first variable resistance pattern 130A and the second conductive line 170. The first variable resistance pattern 130A and the second variable resistance pattern 130B may maintain an amorphous state during a program operation and might not change to a crystalline state after the program operation. In other words, phases of the first variable resistance pattern 130A and the second variable resistance pattern 130B might not change after the program operation.

The first variable resistance pattern 130A and the second variable resistance pattern 130B may be used as selection elements while being data storages. The first variable resistance pattern 130A and the second variable resistance pattern 130B may each include a resistive material, and may have characteristics that reversibly change between different resistance states depending on an applied voltage or current. For example, the first variable resistance pattern 130A or the second variable resistance pattern 130B may include a variable resistance material whose resistance changes without a phase change, and include a chalcogenide element. The first variable resistance pattern 130A and the second variable resistance pattern 130B may each include germanium (Ge), antimony (Sb), arsenic (As), silicon (Si), indium (In), tin (Sn), gallium (Ga), or the like, or include combinations thereof. The first variable resistance pattern 130A and the second variable resistance pattern 130B may each further include a group 16 element. Here, the group 16 element may include at least one of sulfur(S), selenium (Se), and tellurium (Te).

The first variable resistance pattern 130A may have a first thickness T1, and the second variable resistance pattern 130B may have a second thickness T2. The first thickness T1 and the second thickness T2 may be substantially the same as or different from each other. For example, the first thickness T1 and the second thickness T2 may be substantially the same as each other.

A threshold voltage of the memory cell MC may be determined according to compositions of the variable resistance patterns 130A and 130B and a polarity of a program voltage. An operation of applying a negative (−) bias to the first conductive line 110 and applying a positive (+) bias to the second conductive line 170 may be referred to as a forward operation (e.g., a forward program operation), and an operation of applying a positive (+) bias to the first conductive line 110 and applying a negative (−) bias to the second conductive line 170 may be referred to as a reverse operation (e.g., a reverse program operation). Here, during a forward program operation, the memory cell MC may have a low threshold voltage as a set threshold voltage. During a reverse program operation, the memory cell MC may have a high threshold voltage as a reset threshold voltage.

In the case of the memory cell MC performing the forward operation by applying the negative (−) bias to the first conductive line 110, the composition of the first variable resistance pattern 130A adjacent to the first conductive line 110 may affect an initial firing voltage, and the composition of the second variable resistance pattern 130B adjacent to the second conductive line 170 may affect a read window.

As bandgap energy increases, the initial firing voltage for activating the memory cell MC may increase. Accordingly, in order to reduce the initial firing voltage, bandgap energy of the first variable resistance pattern 130A adjacent to the first conductive line 110 may be reduced. The group 16 element is a material having relatively great bandgap energy, and the initial firing voltage may be kept relatively low by limiting a concentration of a first group 16 element included in the first variable resistance pattern 130A to a first concentration. For example, the first variable resistance pattern 130A may include about 18 to about 28 at % of germanium (Ge), about 20 to about 28 at % of arsenic (As), and about 30 to about 45 at % of the first group 16 element. When the amount of the group of 16 elements in the first variable resistance pattern 130A exceeds 45 at %, the initial firing voltage of the first variable resistance pattern 130A may become excessively large to deteriorate operation reliability of the memory cell MC including the first variable resistance pattern 130A. When the amount of the group of 16 elements in the first variable resistance pattern 130A is less than 30 at %, the amount of the group of 16 element may be excessively small to make the first variable resistance pattern 130A improperly function as a memory element as well as a selection element. Here, the group 16 element may be tellurium (Te) to keep the initial firing voltage of the first variable resistance pattern 130A sufficiently low.

The second variable resistance pattern 130B may be located to be spaced apart from the first conductive line 110, and may have less influence on the initial firing voltage than the first variable resistance pattern 130A has. Accordingly, the composition of the second variable resistance pattern 130B may be adjusted so as to increase the read window. As a composition difference between the first variable resistance pattern 130A and the second variable resistance pattern 130B increases, activation energy may increase, and a threshold voltage difference between a set state and a reset state may increase. Accordingly, the second variable resistance pattern 130B may increase the read window by including a second group 16 element at a second concentration higher than the first concentration. The second group 16 element of the second variable resistance pattern 130B may be the same as or different from the first group 16 element of the first variable resistance pattern 130A. For example, the second variable resistance pattern 130B may include about 18 to about 28 at % of germanium (Ge), about 20 to about 28 at % of arsenic (As), and about 45 to about 60 at % of the second group 16 element. When the amount of the group 16 element in the second variable resistance pattern 130B is less than 45 at % or more than 60 at %, the read window may not be sufficiently large to ensure operation reliability of the memory cell MC including the second variable resistance pattern 130B.

During the program operation or a read operation, there may be a change in composition of the variable resistance patterns 130A and 130B. For example, the group 16 elements included in the variable resistance patterns 130A and 130B may move in a positive (+) bias direction. Assuming that the group 16 elements can move between the first variable resistance pattern 130A and the second variable resistance pattern 130B without being significantly interrupted, a composition difference between the first variable resistance pattern 130A and the second variable resistance pattern 130B may occur, and a dimensional change (e.g., a thickness change) may occur due to the composition difference, which may cause reliability deterioration of the semiconductor device. Accordingly, it may be desirable to prevent or reduce the occurrence of the composition difference between the variable resistance patterns 130A and 130B.

The diffusion barrier pattern 140 may electrically connect the first variable resistance pattern 130A and the second variable resistance pattern 130B to each other, and may prevent or reduce the movement of the group 16 elements included in the variable resistance patterns 130A and 130B. The diffusion barrier pattern 140 may be located between the first variable resistance pattern 130A and the second variable resistance pattern 130B. In such a case, when a Fermi energy level is located in the middle, a threshold voltage difference may be the greatest as in the case where the activation energy is the greatest. Accordingly, characteristics of the first variable resistance pattern 130A and the second variable resistance pattern 130B may be improved, and the read window may be increased.

The diffusion barrier pattern 140 may have a third thickness T3. The third thickness T3 may be smaller than the first thickness T1 and the second thickness T2. Here, the third thickness T3 may be about 5 to about 150 Å. The diffusion barrier pattern 140 may include at least one of a conductive material and a dielectric material. As an example, the diffusion barrier pattern 140 may include a conductive material. Here, the third thickness T3 may be about 30 to about 150 Å, and the conductive material may include at least one of C, SiC, SiCN, and CN. When the diffusion barrier pattern 140 includes a conductive material and has a thickness less than 30 Å, the movement of the group 16 elements included in the variable resistance patterns 130A and 130B may not be substantially prevented and it is possible to accelerate the reliability deterioration. When the diffusion barrier pattern 140 includes a conductive material and has a thickness exceeding 150 Å, an additional integration process of the diffusion barrier pattern 140 may be necessary, or an aspect ratio of the memory cell MC may be excessively large to require adjusting associated processes, or both, thereby making the fabrication process complicated and reducing the production yield. As another example, the diffusion barrier pattern 140 may include a dielectric material. Here, the third thickness T3 may be about 5 to about 30 Å, and the dielectric material may include at least one of SiN, SiO₂, HfO₂, ZrO₂, and Al₂O₃. When the diffusion barrier pattern 140 includes a dielectric material and has a thickness less than 5 Å, the diffusion barrier pattern 140 may not properly function as a diffusion barrier to substantially prevent the movement of the group 16 elements between the variable resistance patterns 130A and 130B. When the diffusion barrier pattern 140 includes a dielectric material and has a thickness exceeding 30 Å, the electrical connection between the variable resistance patterns 130A and 130B may be substantially blocked, and the diffusion barrier pattern 140 may be damaged due to electrical stress.

The first liner patterns 150A may extend in the first direction I and surround sidewalls of the memory cells MC. For example, the first liner patterns 150A may be located on sidewalls of the memory cells MC facing each other in the second direction II. The first linear patterns 150A might not be removed in a manufacturing process, and may remain on the sidewalls of the memory cells MC to protect the memory cells MC. The first linear patterns 150A may each include an insulating material such as nitride or oxide.

The second linear patterns 150B may extend in the second direction II and surround sidewalls of the memory cells MC. For example, the second liner patterns 150B may be located on sidewalls of the memory cells MC facing each other in the first direction I. The second linear patterns 150B may each include an insulating material such as nitride or oxide.

The first gap-fill patterns 160A may be located between the memory cells MC. For example, the first gap-fill patterns 160A may be located between the memory cells MC adjacent to each other in the second direction II. The first liner patterns 150A may be located between the first gap-fill patterns 160A and the memory cells MC. The first gap-fill patterns 160A may each include an insulating material such as oxide.

The second gap-fill patterns 160B may be located between the memory cells MC. For example, the second gap-fill patterns 160B may be located between the memory cells MC adjacent to each other in the first direction I. The second liner patterns 150B may be located between the second gap-fill patterns 160B and the memory cells MC. The second gap-fill patterns 160B may each include an insulating material such as oxide.

The first variable resistance pattern 130A may have different properties from those of the second variable resistance pattern 130A to ensure desirable operation characteristics of the memory cell MC including the variable resistance patterns 130A and 130B. In some embodiments, the first variable resistance pattern 130A may include one or more materials, or a composition, or both, having a relatively low bandgap energy, thereby keeping an initial firing voltage of the memory cell MC at a relatively low level. The second variable resistance pattern 130B may include one or more materials, or a composition, or both, having a relatively high bandgap energy, thereby increasing a read window of the memory cell MC. For example, according to the embodiment shown in FIGS. 1A to 1C, the first variable resistance pattern 130A may include the group 16 element at the first concentration that is relatively low. In addition, the second variable resistance pattern 130A may include the group 16 element at the second concentration higher than the first concentration. Accordingly, the initial firing voltage of the memory cell MC may be reduced, and the read window may be increased.

In addition, the diffusion barrier pattern 140 may be located between the first variable resistance pattern 130A and the second variable resistance pattern 130B. The diffusion barrier pattern 140 may electrically connect the first variable resistance pattern 130A and the second variable resistance pattern 130B to each other, and may prevent or reduce the movement of the group 16 elements between the variable resistance patterns 130A and 130B. Accordingly, it is possible to reduce the occurrence of the composition difference between the variable resistance patterns 130A and 130B, and it is thus possible to reduce the reliability deterioration.

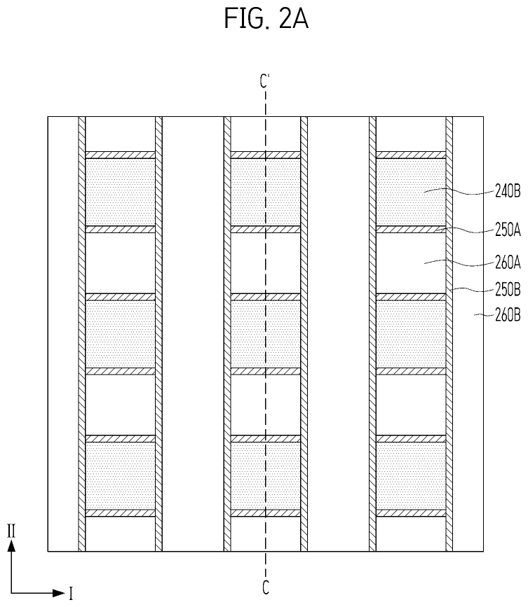

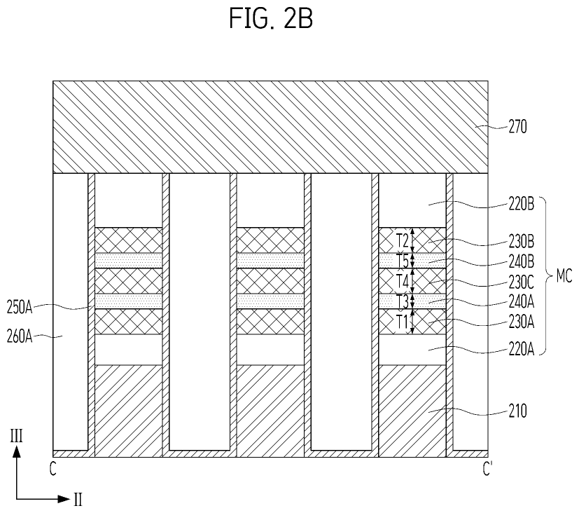

FIGS. 2A and 2B are diagrams for describing a semiconductor device in accordance with an embodiment. FIG. 2A may be a plan view, and FIG. 2B may be a cross-sectional view taken along line C-C′ of FIG. 2A. Hereinafter, the content overlapping with the previously described content may be omitted for the interest of brevity.

Referring to FIGS. 2A and 2B, the semiconductor device may include first conductive lines 210, memory cells MC, and second conductive lines 270 or include a combination thereof. The semiconductor device may further include first liner patterns 250A, second liner patterns 250B, first gap-fill patterns 260A, and second gap-fill patterns 260B or further include a combination thereof.

Each of the memory cells MC may include at least one of a first electrode pattern 220A, a second electrode pattern 220B, a first variable resistance pattern 230A, a second variable resistance pattern 230B, a third variable resistance pattern 230C, a first diffusion barrier pattern 240A, and a second diffusion barrier pattern 240B. The variable resistance patterns 230A, 230B, and 230C and the diffusion barrier patterns 240A and 240B may be alternately stacked. For example, the first diffusion barrier pattern 240A may be located on the first variable resistance pattern 230A, the third variable resistance pattern 230C may be located on the first diffusion barrier pattern 240A, the second diffusion barrier pattern 240B may be located on the third variable resistance pattern 230C, and the second variable resistance pattern 230B may be located on the second diffusion barrier pattern 240B.

The first variable resistance pattern 230A may have a first thickness T1. The second variable resistance pattern 230B may have a second thickness T2. The third variable resistance pattern 230C may have a fourth thickness T4. The first thickness T1, the second thickness T2, and the fourth thickness T4 may be substantially the same as or different from each other. For example, the first thickness T1, the second thickness T2, and the fourth thickness T4 may be substantially the same as each other.

The first variable resistance pattern 230A, the second variable resistance pattern 230B, and the third variable resistance pattern 230C may be used as selection elements while storing data. The first variable resistance pattern 230A, the second variable resistance pattern 230B, and the third variable resistance pattern 230C may include substantially the same material or different materials. The first variable resistance pattern 230A, the second variable resistance pattern 230B, and the third variable resistance pattern 230C may each include a variable resistance material whose resistance changes without a phase change, and include a chalcogenide element. The first variable resistance pattern 230A, the second variable resistance pattern 230B, and the third variable resistance pattern 230C may each include germanium (Ge), antimony (Sb), arsenic (As), silicon (Si), indium (In), tin (Sn), gallium (Ga), or the like, or include combinations thereof. The first variable resistance pattern 230A, the second variable resistance pattern 230B, and the third variable resistance pattern 230C may each further include a group 16 element. Here, the group 16 element may include at least one of sulfur(S), selenium (Se), and tellurium (Te).

The first variable resistance pattern 230A adjacent to the first conductive line 210 may include a group 16 element at a first concentration, and the second variable resistance pattern 230B adjacent to the second conductive line 270 may include a group 16 element at a second concentration higher than the first concentration. In some embodiments, at least one of the variable resistance patterns 230A, 230B, and 230C may include a first group 16 element at a first concentration, and at least one of the remaining variable resistance patterns 230A, 230B, and 230C may include a second group 16 element at a second concentration higher than the first concentration. The first group 16 element may be the same as or different from the second group 16 element. In some embodiments, the third variable resistance pattern 230C may include a group 16 element at a third concentration, which may be higher than the first concentration and lower than the second concentration. However, the third concentration is not limited thereto, and may vary according to embodiments of the present disclosure.

The diffusion barrier patterns 240A and 240B may electrically connect the first variable resistance pattern 230A, the second variable resistance pattern 230B, and the third variable resistance pattern 230C to each other, and may prevent or reduce the movement of the group 16 elements included in the variable resistance patterns 230A, 230B, and 230C. The first diffusion barrier pattern 240A may be located between the first variable resistance pattern 230A and the third variable resistance pattern 230C. The second diffusion barrier pattern 240B may be located between the third variable resistance pattern 230C and the second variable resistance pattern 230B.

The first diffusion barrier pattern 240A may have a third thickness T3. The second diffusion barrier pattern 240B may have a fifth thickness T5. The third thickness T3 and the fifth thickness T5 may be substantially the same as or different from each other. Here, the third thickness T3 and the fifth thickness T5 may be 5 to 150 Å. The third thickness T3 and the fifth thickness T5 may be smaller than the first thickness T1, the second thickness T2, and the fourth thickness T4.

The first diffusion barrier pattern 240A and the second diffusion barrier pattern 240B may include substantially the same material or different materials. The first diffusion barrier pattern 240A or the second diffusion barrier pattern 240B may include at least one of a conductive material and a dielectric material. As an example, the first diffusion barrier pattern 240A and the second diffusion barrier pattern 240B may each include a conductive material or a dielectric material. As another example, the first diffusion barrier pattern 240A may include a conductive material, and the second diffusion barrier pattern 240B may include a dielectric material. Here, the conductive material may include at least one of C, SiC, SiCN, and CN, and the dielectric material may include at least one of SiN, SiO₂, HfO₂, ZrO₂, and Al₂O₃.

When the diffusion barrier patterns 240A and 240B each include a conductive material, the thicknesses T3 and T5 of the diffusion barrier patterns 240A and 240B may be 30 to 150 Å. Here, this is because when the thicknesses T3 and T5 of the diffusion barrier patterns 240A and 240B are less than 30 Å, the movement of the group 16 elements included in the variable resistance patterns 230A, 230B, and 230C may not be substantially prevented and it is possible to accelerate the reliability deterioration. When the diffusion barrier patterns 240A and 240B each include a dielectric material, the thicknesses T3 and T5 of the diffusion barrier patterns 240A and 240B may be 5 to 30 Å. Here, this is because when the thicknesses T3 and T5 of the diffusion barrier patterns 240A and 240B exceed 30 Å, the electrical connection between the variable resistance patterns 230A, 230B, and 230C may be substantially blocked, and the diffusion barrier patterns 240A and 240B may be damaged due to electrical stress.

For reference, although not illustrated in FIGS. 2A and 2B, the memory cell MC may include an additional variable resistance pattern and an additional diffusion barrier pattern in addition to the variable resistance patterns 230A, 230B, and 230C and the diffusion barrier patterns 240A and 240B. In other words, the numbers of variable resistance patterns and diffusion barrier patterns included in the memory cell MC are not limited to the embodiment shown in FIGS. 2A and 2B of the present disclosure.

According to the structure described above, the memory cell MC may include three or more variable resistance patterns 230A, 230B, and 230C. The diffusion barrier patterns 240A and 240B may be located between the variable resistance patterns 230A, 230B and 230C. The diffusion barrier patterns 240A and 240B may include different materials and have different thicknesses. The occurrence of a composition difference between the variable resistance patterns 230A, 230B, and 230C may be reduced by adjusting the materials and/or the thicknesses of the diffusion barrier patterns 240A and 240B.

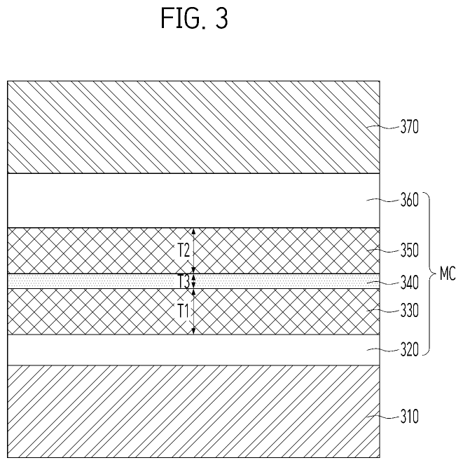

FIG. 3 is a diagram for describing a manufacturing method of a semiconductor device in accordance with an embodiment. Hereinafter, the content overlapping with the previously described content may be omitted for the interest of brevity.

Referring to FIG. 3, a first conductive layer 310 may be formed. The first conductive layer 310 may be a word line or a bit line. A first electrode layer 320 may be formed on the first conductive layer 310. The first electrode layer 320 may be a portion of the first conductive layer 310 or may be electrically connected to the first conductive layer 310. The first conductive layer 310 or the first electrode layer 320 may include a conductive material such as tungsten.

A first variable resistance layer 330 may be formed on the first electrode layer 320. The first variable resistance layer 330 may include a chalcogenide element. The first variable resistance layer 330 may include germanium (Ge), antimony (Sb), arsenic (As), silicon (Si), indium (In), tin (Sn), gallium (Ga), or the like, or include combinations thereof. The first variable resistance layer 330 may further include a group 16 element at a first concentration. Here, the group 16 element may include at least one of sulfur(S), selenium (Se), and tellurium (Te). The first variable resistance layer 330 may have a first thickness T1.

A diffusion barrier layer 340 may be formed on the first variable resistance layer 330. The diffusion barrier layer 340 may include at least one of a conductive material and a dielectric material. Here, the conductive material may include at least one of C, SiC, SiCN, and CN. The dielectric material may include at least one of SiN, SiO₂, HfO₂, ZrO₂, and Al₂O₃. The diffusion barrier layer 340 may have a third thickness T3. Here, the third thickness T3 may be 30 to 150 Å. As an example, when the diffusion barrier layer 340 includes the conductive material, the third thickness T3 may be 30 to 150 Å. As another example, when the diffusion barrier layer 340 includes the dielectric material, the third thickness T3 may be 5 to 30 Å.

A second electrode layer 360 may be formed on the diffusion barrier layer 340. A second conductive layer 370 may be formed on the second electrode layer 360. The second conductive layer 370 may be a word line or a bit line. The second electrode layer 360 may be a portion of the second conductive layer 370 or may be electrically connected to the second conductive layer 370. The second electrode layer 360 or the second conductive layer 370 may include a conductive material such as tungsten.

The second variable resistance layer 350 may be formed on the diffusion barrier layer 340. Consequently, a memory cell MC including the first electrode layer 320, the first variable resistance layer 330, the diffusion barrier layer 340, the second variable resistance layer 350, and the second electrode layer 360 may be formed. The second variable resistance layer 350 may include a material that is substantially the same as or different from that of the first variable resistance layer 330. The second variable resistance layer 350 may have a second thickness T2. Here, the second thickness T2 may be substantially the same as or different from the first thickness T1. For example, the second thickness T2 may be substantially the same as the first thickness T1.

The first variable resistance layer 330 and the second variable resistance layer 350 may be used as selection elements while being data storages. The first variable resistance layer 330 and the second variable resistance layer 350 may maintain an amorphous state during a program operation and might not change to a crystalline state after the program operation. In other words, phases of the first variable resistance layer 330 and the second variable resistance layer 350 might not change after the program operation.

A threshold voltage of the memory cell MC may be determined according to compositions of the variable resistance layers 330 and 350 and a polarity of a program voltage. In the case of the memory cell MC performing a forward operation by applying a negative (−) bias to the first conductive layer 310, the composition of the first variable resistance layer 330 adjacent to the first conductive layer 310 may affect an initial firing voltage, and the composition of the second variable resistance layer 350 adjacent to the second conductive layer 370 may affect a read window.

As bandgap energy increases, the initial firing voltage for activating the memory cell MC may increase. Accordingly, in order to reduce the initial firing voltage, bandgap energy of the first variable resistance layer 330 adjacent to the first conductive layer 310 may be reduced. The group 16 element is a material having great bandgap energy, and the initial firing voltage may be kept relatively low by limiting a concentration of the group 16 element included in the first variable resistance layer 330 to the first concentration. For example, the first variable resistance layer 330 may include about 18 to about 28 at % of germanium (Ge), about 20 to about 28 at % of arsenic (As), and about 30 to about 45 at % of a group 16 element. Here, the group 16 element may be tellurium (Te).

The second variable resistance layer 350 may be formed to be spaced apart from the first conductive layer 310, and may have less influence on the initial firing voltage than the first variable resistance layer 330 has. Accordingly, the composition of the second variable resistance layer 350 may be adjusted so as to increase the read window. As a composition difference between the first variable resistance layer 330 and the second variable resistance layer 350 increases, activation energy may increase, and a threshold voltage difference between a set state and a reset state may increase. Accordingly, the second variable resistance layer 350 may increase the read window by including a group 16 element at a second concentration higher than the first concentration. For example, the second variable resistance layer 350 may include about 18 to about 28 at % of germanium (Ge), about 20 to about 28 at % of arsenic (As), and about 45 to about 60 at % of a group 16 element.

During the program operation or a read operation, there may be a change in composition of the variable resistance layers 330 and 350. For example, the group 16 elements included in the variable resistance layers 330 and 350 may move in a positive (+) bias direction. Assuming that the group 16 elements can move between the first variable resistance layer 330 and the second variable resistance layer 350 without being significantly interrupted, a composition difference between the first variable resistance layer 330 and the second variable resistance layer 350 may occur, and a dimensional change (e.g., a thickness change) may occur due to the composition difference, which may cause reliability deterioration of the semiconductor device. Accordingly, it may be desirable to prevent or reduce the occurrence of the composition difference between the variable resistance layers 330 and 350.

According to an embodiment of the present disclosure, the diffusion barrier layer 340 may be formed between the first variable resistance layer 330 and the second variable resistance layer 350, may electrically connect the first variable resistance layer 330 and the second variable resistance layer 350 to each other, and may prevent or reduce the movement of the group 16 elements included in the variable resistance layers 330 and 350.

In addition, the diffusion barrier layer 340 may have the third thickness T3. The third thickness T3 may be smaller than the first thickness T1 and the second thickness T2. Here, the third thickness T3 may be 5 to 150 Å. When the diffusion barrier layer 340 includes the conductive material and has a thickness less than 30 Å, the movement of the group 16 elements included in the variable resistance layers 330 and 350 may not be substantially prevented and it is possible to accelerate the reliability deterioration. When the diffusion barrier layer 340 includes a dielectric material and has a thickness exceeding 30 Å, the electrical connection between the variable resistance layers 330 and 350 may be substantially blocked, and the diffusion barrier layer 340 may be damaged due to electrical stress.

According to the manufacturing method described above, the first variable resistance layer 330 may include the group 16 element at the first concentration that is relatively low. In addition, the second variable resistance layer 350 may include the group 16 element at the second concentration higher than the first concentration. Accordingly, the initial firing voltage of the memory cell MC may be reduced, and the read window may be increased.

In addition, the diffusion barrier layer 340 may be formed between the first variable resistance layer 330 and the second variable resistance layer 350. The diffusion barrier pattern 340 may electrically connect the variable resistance layers 330 and 350 to each other, and may prevent or reduce the movement of the group 16 elements between the variable resistance layers 330 and 350. Accordingly, it is possible to reduce the occurrence of the composition difference between the variable resistance layers 330 and 350, and it is thus possible to reduce the reliability deterioration.

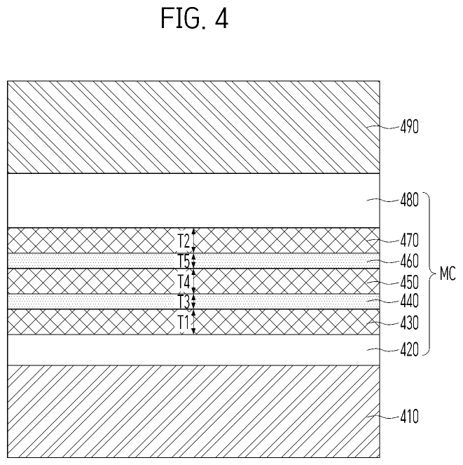

FIG. 4 is a diagram for describing a manufacturing method of a semiconductor device in accordance with an embodiment. Hereinafter, the content overlapping with the previously described content may be omitted for the interest of brevity.

Referring to FIG. 4, a first electrode layer 420 may be formed on a first conductive layer 410. The first electrode layer 420 may be a portion of the first conductive layer 410. The first conductive layer 410 may be a word line or a bit line.

Subsequently, variable resistance layers 430, 450, and 470 and diffusion barrier layers 440 and 460 alternately stacked on the first electrode layer 420 may be formed. For example, a first variable resistance layer 430 may be formed on the first electrode layer 420. Subsequently, a first diffusion barrier layer 440 may be formed on the first variable resistance layer 430. Subsequently, a third variable resistance layer 450 may be formed on the first diffusion barrier layer 440. Subsequently, a second diffusion barrier layer 460 may be formed on the third variable resistance layer 450. Subsequently, a second variable resistance layer 470 may be formed on the second diffusion barrier layer 460.

The first variable resistance layer 430 may include a group 16 element at a first concentration, and the second variable resistance layer 470 may include a group 16 element at a second concentration higher than the first concentration. The third variable resistance layer 450 may include a group 16 element at a third concentration. Here, the group 16 element may include at least one of sulfur(S), selenium (Se), and tellurium (Te). In some embodiments, the third concentration may be higher than the first concentration and may be lower than the second concentration. However, the third concentration is not limited thereto, and may vary according to embodiments of the present disclosure.

The first variable resistance layer 430 may have a first thickness T1, the second variable resistance layer 470 may have a second thickness T2, and the third variable resistance layer 450 may have a fourth thickness T4. Here, the first thickness T1, the second thickness T2, and the fourth thickness T4 may be substantially the same as or different from each other. For example, the first thickness T1, the second thickness T2, and the fourth thickness T4 may be substantially the same as each other.

The first diffusion barrier layer 440 may have a third thickness T3, and the second diffusion barrier layer 460 may have a fifth thickness T5. The third thickness T3 and the fifth thickness T5 may be 5 to 150 Å. The third thickness T3 and the fifth thickness T5 may be substantially the same as or different from each other. For example, the third thickness T3 and the fifth thickness T5 may be different from each other.

The diffusion barrier layers 440 and 460 may each include at least one of a dielectric material and a conductive material. For example, the first diffusion barrier layer 440 may include a dielectric material, and the second diffusion barrier layer 460 may include a conductive material. In such a case, the first diffusion barrier layer 440 may have a thickness of 5 to 30 Å, and the second diffusion barrier layer 460 may have a thickness of 30 to 150 Å.

Subsequently, a second electrode layer 480 may be formed on the second variable resistance layer 470. Consequently, a memory cell MC including the first electrode layer 420, the second electrode layer 480, the second variable resistance layer 470, the second diffusion barrier layer 460, the third variable resistance layer 450, the first diffusion barrier layer 440, and the first variable resistance layer 430 may be formed. Subsequently, a second conductive layer 490 may be formed on the second electrode layer 480. The second electrode layer 480 may be a portion of the second conductive layer 490. The second conductive layer 490 may be a word line or a bit line.

According to the manufacturing method described above, the variable resistance layers 430, 450, and 470 and the diffusion barrier layers 440 and 460 alternately stacked between the first electrode layer 420 and the second electrode layer 480 may be formed. The occurrence of a composition difference between the variable resistance layers 430, 450, and 470 may be reduced by adjusting the materials and/or the thicknesses of the diffusion barrier layers 440 and 460.

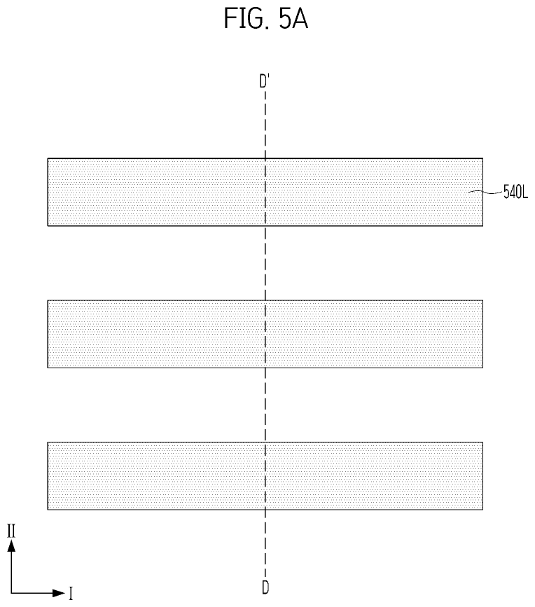

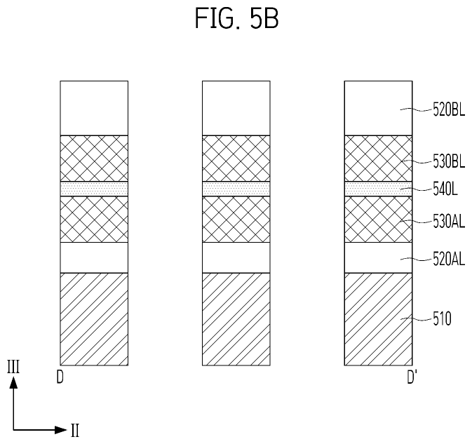

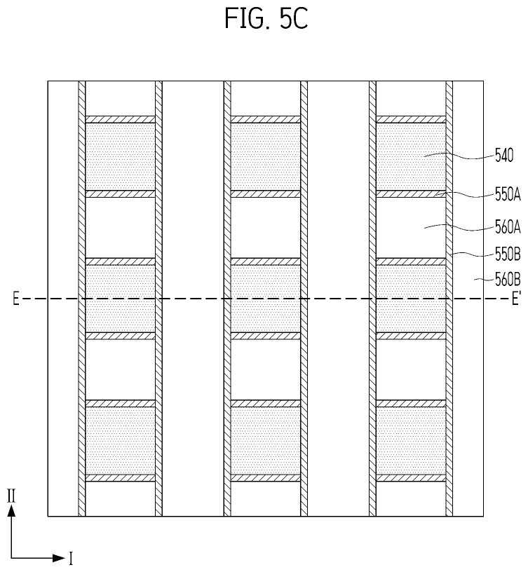

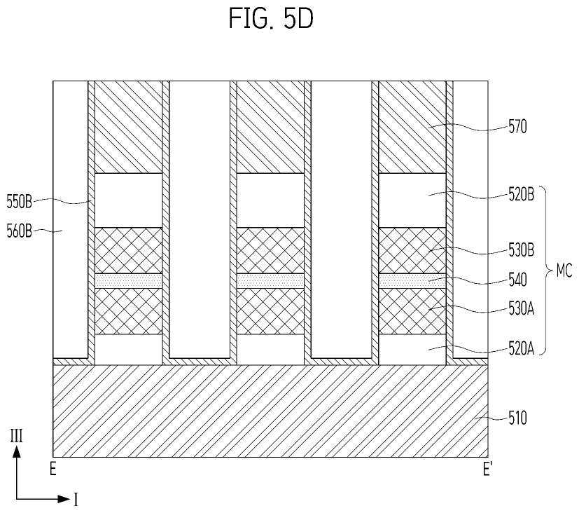

FIGS. 5A to 5D are diagrams for describing a manufacturing method of a semiconductor device in accordance with an embodiment. FIGS. 5A and 5C may be plan views, FIG. 5B may be a cross-sectional view taken along line D-D′ of FIG. 5A, and FIG. 5D may be a cross-sectional view taken along line E-E′ of FIG. 5C. Hereinafter, the content overlapping with the previously described content may be omitted for the interest of brevity.

Referring to FIGS. 5A and 5B, a first conductive layer may be formed. Subsequently, a first electrode layer may be formed on the first conductive layer. Subsequently, a first variable resistance layer may be formed on the first electrode layer. Subsequently, a diffusion barrier layer may be formed on the first variable resistance layer. Subsequently, a second variable resistance layer may be formed on the diffusion barrier layer. Subsequently, a second electrode layer may be formed on the second variable resistance layer. In an embodiment, the first variable resistance layer may include a first group 16 element at a first concentration, and the second variable resistance layer may include a second group 16 element at a second concentration higher than the first concentration. The first group 16 element may be the same as or different from the second group 16 element.

For reference, although not illustrated in FIGS. 5A to 5D, variable resistance layers and diffusion barrier layers may be alternately stacked between the first electrode layer and the second electrode layer. In other words, a plurality of diffusion barrier layers may be formed between the first electrode layer and the second electrode layer. For example, a first diffusion barrier layer may be disposed between a first variable resistance layer and a second variable resistance layer, a second diffusion barrier layer may be disposed between the second variable resistance layer and a third variable resistance layer, and the first and second diffusion barrier layers and the first, second, and third variable resistance layers may be disposed between the first electrode layer and the second electrode layer.

Subsequently, a second electrode line 520BL, a second variable resistance line 530BL, a diffusion barrier line 540L, a first variable resistance line 530AL, and a first electrode line 520AL may be formed by etching the second electrode layer, the second variable resistance layer, the diffusion barrier layer, the first variable resistance layer, and the first electrode layer. A first conductive line 510 may be formed by etching the first conductive layer. The first conductive line 510 may extend in the first direction I. The first conductive line 510 may be a word line or a bit line. In some embodiments, the first conductive line 510 may be formed before the second electrode layer is formed.

The first variable resistance line 530AL and the second variable resistance line 530BL may each include a chalcogenide element. The first variable resistance line 530AL and the second variable resistance line 530BL may each further include a group 16 element. Here, the group 16 element may include at least one of sulfur(S), selenium (Se), and tellurium (Te). For example, the first variable resistance line 530AL may include a group 16 element at a first concentration, and the second variable resistance line 530BL may include a group 16 element at a second concentration higher than the first concentration.

The diffusion barrier line 540L may include at least one of a dielectric material and a conductive material. The diffusion barrier line 540L may electrically connect the variable resistance lines 530AL and 530BL to each other. The diffusion barrier line 540L may have a relatively smaller thickness than the variable resistance lines 530AL and 530BL.

Referring to FIGS. 5C and 5D, a first liner layer may be formed. The first liner layer may be formed along profiles of the first conductive line 510, the second electrode line 520BL, the second variable resistance line 530BL, the diffusion barrier line 540L, the first variable resistance line 530AL, and the first electrode line 520AL that extend in the first direction I. The first liner layer may include an insulating material such as oxide or nitride.

Subsequently, a first gap-fill layer may be formed. The first gap-fill layer extending in the first direction I may be formed to fill a space between the first liner layers. The first gap-fill layer may include an insulating material such as oxide.

Subsequently, a second conductive layer may be formed on the second electrode line 520BL. Before the second conductive layer is formed, the first gap-fill layer and the first liner layer may be planarized until an upper surface of the second electrode line 520BL is exposed. In such a case, the first gap-fill layer may be separated into first gap-fill patterns 560A spaced apart from each other, and the first liner layer may be separated into first liner patterns 550A spaced apart from each other.

Subsequently, a second conductive line 570 may be formed by etching the second conductive layer. The second conductive line 570 may extend in the second direction II intersecting the first direction I. The second conductive line 570 may be a word line or a bit line. As an example, when the first conductive line 510 is a word line, the second conductive line 570 may be a bit line. As another example, when the first conductive line 510 is a bit line, the second conductive line 570 may be a word line.

Subsequently, a second electrode pattern 520B, a second variable resistance pattern 530B, a diffusion barrier pattern 540, a first variable resistance pattern 530A, and a first electrode pattern 520A may be formed by etching the second electrode line 520BL, the second variable resistance line 530BL, the diffusion barrier line 540L, the first variable resistance line 530AL, and the first electrode line 520AL. Consequently, a memory cell MC including the second electrode pattern 520B, the second variable resistance pattern 530B, the diffusion barrier pattern 540, the first variable resistance pattern 530A, and the first electrode pattern 520A may be formed.

Subsequently, a second liner layer may be formed. The second liner layer may be formed along profiles of the second conductive line 570, the second electrode pattern 520B, the second variable resistance pattern 530B, the diffusion barrier pattern 540, the first variable resistance pattern 530A, and the first electrode pattern 520A that extend in the second direction II. The second liner layer may include an insulating material such as oxide or nitride.

Subsequently, a second gap-fill layer may be formed. The second gap-fill layer extending in the second direction II may be formed to fill a space between the second liner layers 550B. The second gap-fill layer may include an insulating material such as oxide.

Subsequently, the second gap-fill layer and the second liner layer may be planarized until an upper surface of the second conductive line 570 is exposed. In such a case, the second gap-fill layer may be separated into second gap-fill patterns 560B spaced apart from each other, and the second liner layer may be separated into second liner patterns 550B spaced apart from each other.

According to the manufacturing method described above, the first variable resistance pattern 530A including the group 16 element at the first concentration that is relatively low may be formed. In addition, the second variable resistance pattern 530B including the group 16 element at the second concentration higher than the first concentration may be formed. Accordingly, the initial firing voltage of the memory cell MC may be reduced, and the read window may be increased.

In addition, the diffusion barrier pattern 540 may be formed between the first variable resistance pattern 530A and the second variable resistance pattern 530B. The diffusion barrier pattern 540 may electrically connect the variable resistance patterns 530A and 530B to each other, and may prevent or reduce the movement of the group 16 elements between the variable resistance patterns 530A and 530B. Accordingly, it is possible to reduce the occurrence of the composition difference between the variable resistance patterns 530A and 530B, and it is thus possible to reduce the reliability deterioration.

Although embodiments according to the technical idea of the present disclosure have been described above with reference to the accompanying drawings, this is only for explaining the embodiments according to the concept of the present disclosure, and various embodiments of the present disclosure are not limited to the above-described embodiments. Various types of substitutions, modifications, and changes for the embodiments may be possible.

What is claimed is:

1. A semiconductor device comprising:
a first conductive line;
a second conductive line intersecting the first conductive line;
a first variable resistance pattern located between the first conductive line and the second conductive line and including a first group 16 element at a first concentration;
a second variable resistance pattern located between the first variable resistance pattern and the second conductive line and including a second group 16 element at a second concentration higher than the first concentration; and
a diffusion barrier pattern located between the first variable resistance pattern and the second variable resistance pattern.

2. The semiconductor device of claim 1, wherein the first variable resistance pattern includes about 18 to about 28 at % of germanium (Ge), about 20 to about 28 at % of arsenic (As), and about 30 to about 45 at % of the first group 16 element.

3. The semiconductor device of claim 2, wherein the second variable resistance pattern includes about 18 to about 28 at % of germanium (Ge), about 20 to about 28 at % of arsenic (As), and about 45 to about 60 at % of the second group 16 element different from the first group 16 element of the first variable resistance pattern.

4. The semiconductor device of claim 2, wherein the first group 16 element includes at least one of sulfur(S), selenium (Se), and tellurium (Te).

5. The semiconductor device of claim 1, wherein the first variable resistance pattern has a first thickness, the second variable resistance pattern has a second thickness, and the diffusion barrier pattern has a third thickness smaller than the first thickness and the second thickness.

6. The semiconductor device of claim 5, wherein the third thickness is about 5 to about 150 Å.

7. The semiconductor device of claim 1, wherein the diffusion barrier pattern includes at least one of a conductive material and a dielectric material.

8. The semiconductor device of claim 7, wherein the conductive material includes at least one of C, SiC, SiCN, and CN.

9. The semiconductor device of claim 7, wherein the dielectric material includes at least one of SIN, SiO₂, HfO₂, ZrO₂, and Al₂O₃.

10. The semiconductor device of claim 1, wherein the first variable resistance pattern and the second variable resistance pattern maintain their phases after a program operation.

11. The semiconductor device of claim 1, wherein the first group 16 element of the first variable resistance pattern is the same as the second group 16 element of the second variable resistance pattern.

12. A semiconductor device comprising:
a first conductive line;
a second conductive line intersecting the first conductive line; and
a memory cell connected between the first conductive line and the second conductive line and including variable resistance patterns and diffusion barrier patterns that are alternately stacked, the variable resistance patterns maintaining their phases after a program operation.

13. The semiconductor device of claim 12, wherein at least one of the variable resistance patterns includes a first group 16 element at a first concentration, and at least one of the remaining variable resistance patterns includes a second group 16 element at a second concentration higher than the first concentration.

14. The semiconductor device of claim 13, wherein the first concentration is about 30 to about 45 at %, and the second concentration is about 45 to about 60 at %.

15. The semiconductor device of claim 13, wherein each of the first and second group 16 elements includes at least one of sulfur(S), selenium (Se), and tellurium (Te).

16. The semiconductor device of claim 12, wherein at least one of the variable resistance patterns has a first thickness, and the diffusion barrier patterns each have a third thickness smaller than the first thickness.

17. The semiconductor device of claim 16, wherein the third thickness is about 5 to about 150 Å.

18. The semiconductor device of claim 12, wherein the diffusion barrier patterns each include at least one of a conductive material and a dielectric material.

19. The semiconductor device of claim 18, wherein the conductive material includes at least one of C, SiC, SiCN, and CN.

20. The semiconductor device of claim 18, wherein the dielectric material includes at least one of SiN, SiO₂, HfO₂, ZrO₂, and Al₂O₃.

21. A manufacturing method of a semiconductor device, the manufacturing method comprising:
forming a first electrode layer;
forming a first variable resistance layer on the first electrode layer, the first variable resistance layer including a first group 16 element at a first concentration;
forming a diffusion barrier layer on the first variable resistance layer;
forming a second variable resistance layer on the diffusion barrier layer, the second variable resistance layer including a second group 16 element at a second concentration higher than the first concentration; and
forming a second electrode layer on the second variable resistance layer.

22. The manufacturing method of claim 21, further comprising:
forming a second electrode line, a second variable resistance line, a diffusion barrier line, a first variable resistance line, and a first electrode line by etching the second electrode layer, the second variable resistance layer, the diffusion barrier layer, the first variable resistance layer, and the first electrode layer; and
forming a memory cell including a second electrode pattern, a second variable resistance pattern, a diffusion barrier pattern, a first variable resistance pattern, and a first electrode pattern by etching the second electrode line, the second variable resistance line, the diffusion barrier line, the first variable resistance line, and the first electrode line.

23. The manufacturing method of claim 22, wherein the first variable resistance pattern and the second variable resistance pattern maintain their phases after a program operation.

24. The manufacturing method of claim 21, wherein the first variable resistance layer includes about 18 to about 28 at % of germanium (Ge), about 20 to about 28 at % of arsenic (As), and about 30 to about 45 at % of the first group 16 element.

25. The manufacturing method of claim 24, wherein the second variable resistance layer includes about 18 to about 28 at % of germanium (Ge), about 20 to about 28 at % of arsenic (As), and about 45 to about 60 at % of the second group 16 element different from the first group 16 element of the first variable resistance layer.

26. The manufacturing method of claim 24, wherein each of the first and second group 16 elements includes at least one of sulfur(S), selenium (Se), and tellurium (Te).

27. The manufacturing method of claim 21, wherein the first variable resistance layer has a first thickness, the second variable resistance layer has a second thickness, and the diffusion barrier layer has a third thickness smaller than the first thickness and the second thickness.

28. The manufacturing method of claim 27, wherein the third thickness is about 5 to about 150 Å.

29. The manufacturing method of claim 21, wherein the diffusion barrier layer includes at least one of a conductive material and a dielectric material.

30. The manufacturing method of claim 29, wherein the conductive material includes at least one of C, SiC, SiCN, and CN.

31. The manufacturing method of claim 29, wherein the dielectric material includes at least one of SiN, SiO₂, HfO₂, ZrO₂, and Al₂O₃.
